(19) United States
(12) Patent Application Publication
(10) Pub. No.: US 2007/0082472 A1
(43) Pub. Date: Apr. 12, 2007

(54) METHOD OF MANUFACTURING CONTACT HOLE

(76) Inventors: Kao-Tun Chen, Hsinchu City (TW); Li-Tung Hsiao, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,249

(22) Filed: Dec. 21, 2005

(30) Foreign Application Priority Data
Oct. 11, 2005 (TW) 94135336

(51) Int. Cl. H01L 21/44

(52) U.S. Cl. 438/597

(57) ABSTRACT

A method of manufacturing contact hole is provided. First, a mask layer is formed on a substrate and a plurality of trenches is formed in the mask layer along two directions that cross over each other. The depth of the trenches is not greater than the thickness of the mask layer. However, there is an opening in the mask layer in the place where the trenches cross over each other. The opening exposes the substrate. Part of the substrate exposed by the opening is removed to form a contact hole in the substrate. In photolithography, it is easier to form lines than to form dots. Hence, the dimensions of contact holes are more precisely controlled.

### CROSS-REFERENCE TO RELATED APPLICATION

This application claims the priority benefit of Taiwan application serial no. 94135336, filed on Oct. 11, 2005. All disclosure of the Taiwan application is incorporated herein by reference.

### BACKGROUND OF THE INVENTION

1. Field of the Invention

The present invention relates to a method of manufacturing semiconductor device. More particularly, the present invention relates to a method of manufacturing contact hole that uses a mask.

2. Description of the Related Art

With the rapid development of integrated circuit fabrication technologies, device miniaturization and integration is a definite trend and an important target issue for the manufacturing industry. However, as the size of the devices continues to shrink, the dimension and the width of interconnecting lines linking up various devices also reduce. Therefore, the process of fabricating these devices has become increasingly difficult.

For example, due to the size reduction, optical properties of material is harder to gauge and the photolithographic process has encountered some machine processing limits and physical limit in optical properties. As a result, the process of fabricating contact holes using photolithographic technique is increasingly difficult and the critical dimension and the alignment accuracy of the contact hole are increasingly difficult to control. Consequently, the cost of production continues to rise while the yield continues to drop.

To increase the capacity for controlling the critical dimension of a contact hole, the method of fabricating the contact hole must be improved under the present equipment and fabricating conditions. Alternatively, the processing window has to be increased to lower the production cost.

### SUMMARY OF THE INVENTION

Accordingly, at least one objective of the present invention is to provide a method of manufacturing contact hole that can increase the capability of controlling the critical dimension.

At least another objective of the present invention is to provide a method of manufacturing contact hole that can increase the process window and reduce cost.

To achieve these and other advantages and in accordance with the purpose of the invention, as embodied and broadly described herein, the invention provides a method of manufacturing a contact hole. First, a substrate is provided. A mask layer is formed over the substrate and at least a first trench is formed in the mask layer. The depth of the first trench is not greater than the thickness of the mask layer and the first trench extends in a first direction. Thereafter, at least a second trench is formed in the mask layer. The depth of the second trench is not greater than the thickness of the mask layer and the second trench extends in a second direction. The second direction crosses over the first direction. There is an opening in the mask layer in the location where the first trench and the second trench cross over each other. The opening exposes the substrate. Then, part of the substrate exposed by the opening is removed to form a contact hole in the substrate.

In one embodiment of the present invention, the step of forming at least one first trench in the mask layer includes forming a first patterned photoresist layer over the mask layer. Then, using the first patterned photoresist layer as a mask, part of the mask layer is removed to form at least a first trench in the mask layer. After that, the first patterned photoresist layer is removed.

In one embodiment of the present invention, the first patterned photoresist layer is fabricated using a positive photoresist material or a negative photoresist material, for example.

In one embodiment of the present invention, the step of forming at least one second trench in the mask layer includes forming a second patterned photoresist layer over the mask layer. Then, using the second patterned photoresist layer as a mask, part of the mask layer is removed to form at least a second trench in the mask layer.

In one embodiment of the present invention, after forming the second trench in the mask layer but before removing part of the substrate exposed by the opening, further includes removing the second patterned photoresist layer.

In one embodiment of the present invention, the first trench exposes a portion of the substrate.

In one embodiment of the present invention, the second patterned photoresist layer is fabricated using a positive photoresist material or a negative photoresist material, for example.

In one embodiment of the present invention, the mask layer is fabricated using silicon nitride, for example.

In photolithography, the process of fabricating a contact hole is more difficult than fabricating a line or a trench. Therefore, the present invention utilizes the stability and high etching selectivity of a mask layer. In the photolithographic process, trench patterns are used to fabricate the mask for forming the contact hole so that the contact hole can have a bigger processing window. In this way, the process of fabricating the contact hole has the same processing capability as fabricating a line or a trench. Furthermore, in the fabrication of photomasks, a line pattern is much easier to fabricate and far more accurate than a dot pattern so that the production cost can be significantly reduced. Moreover, in the design of photomasks, the optical characteristics of line patterns are much easier to manage so that the time for putting up a design is shortened and the amount of information related to each photomask is substantially reduced. In addition, the present invention also lowers the degree of difficulties in the manufacturing process and simplifies the processing steps to produce a highly stable structure.

The present invention also provides a method of fabricating a contact hole. First, a substrate is provided. A mask layer is formed over the substrate and then a first photoresist layer is formed over the mask layer. Then, using a first photomask, a first exposure process and a first development of the first photoresist layer are performed in sequence to form at least a first trench that exposes the mask layer in the first photoresist layer. The first photomask has at least a first line opening. The first line opening in the photomask and the first trench in the first photoresist layer extend in a first direction. Thereafter, using the first photoresist layer as a mask, a first etching operation is performed to form at least a second trench in the mask layer. The second trench has a depth not greater than the thickness of the mask layer. After that, the first photoresist layer is removed and then a second photoresist layer is formed over the substrate. Then, using a second photomask, a second exposure process and a second developing process of the second photoresist layer is performed in sequence to form at least a third trench that exposes the mask layer in the second photoresist layer. The second photomask has at least a second line opening. The second line opening in the second photomask and the third trench in the second photoresist layer extend in a second direction such that the second direction intersects the first direction. After that, using the second photoresist layer as a mask, a second etching operation is performed to form a fourth trench in the mask layer. The fourth trench has a depth not greater than the thickness of the mask layer. Furthermore, the place where the second trench and the fourth trench cross over each other exposes the substrate. Finally, part of the exposed substrate is removed.

In one embodiment of the present invention, after forming the fourth trench but before removing part of the exposed substrate, further includes removing the second photoresist layer.

In one embodiment of the present invention, the first photoresist layer is fabricated using a positive photoresist material or a negative photoresist material, for example.

In one embodiment of the present invention, the second patterned photoresist layer is fabricated using a positive photoresist material or a negative photoresist material, for example.

In one embodiment of the present invention, the mask layer is fabricated using silicon nitride, for example.

In the present invention, two separate masks including a mask layer with trench pattern thereon and a patterned photoresist layer is used to form a contact hole in the substrate so that the harder-to-produce contact hole in a photolithographic process can have a wider processing window. In addition, the optical characteristics of a line pattern are much easier to manage than a dot pattern so that design and fabrication of line pattern on a photomask is much simpler. As a result, the production cost can be significantly reduced.

It is to be understood that both the general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1E are perspective views showing the steps for fabricating contact holes on a substrate according to a first embodiment of the present invention.

FIG. 2 is a top view of FIG. 1D.

FIGS. 3A through 3D are perspective views showing the steps for fabricating contact holes on a substrate according to a second embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

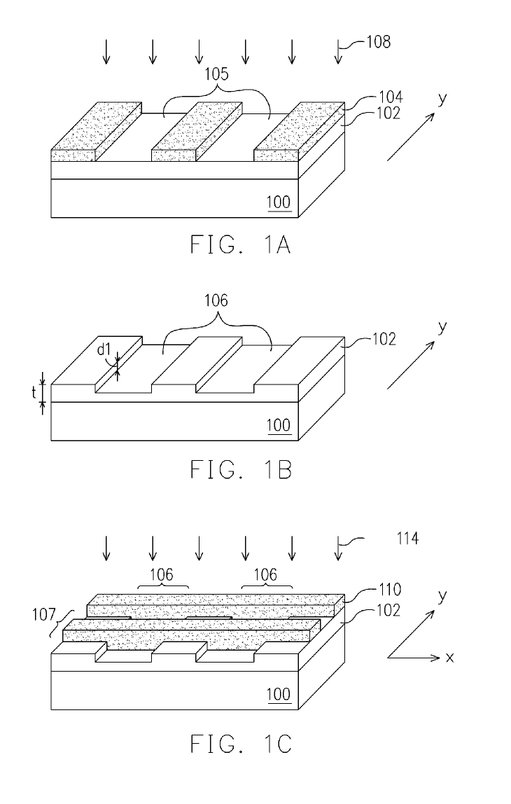

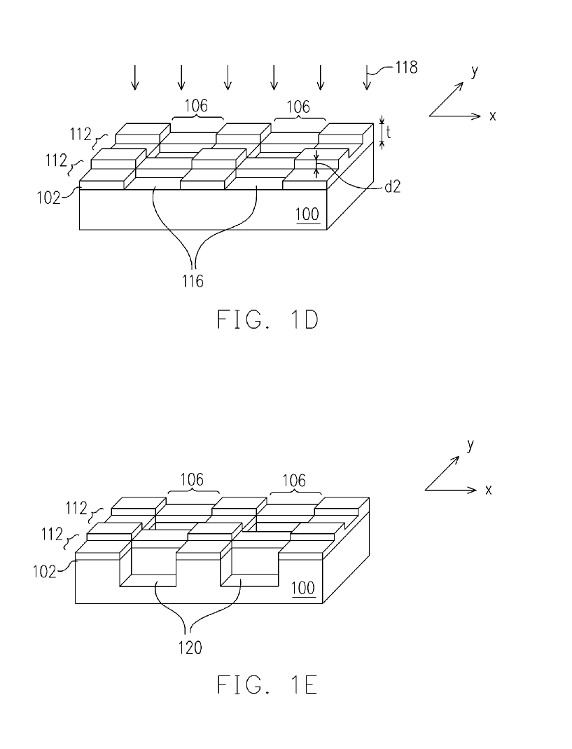

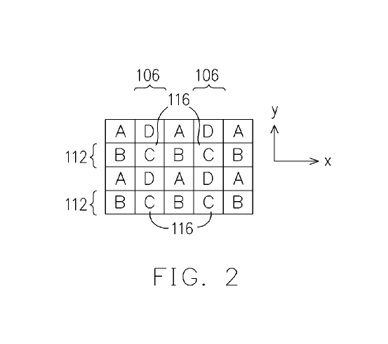

FIGS. 1A through 1E are perspective views showing the steps for fabricating contact holes on a substrate according to a first embodiment of the present invention. The term ‘contact hole’ is a generic term for all kinds of contact holes, via holes and other types having a similar structure.

First, as shown in FIG. 1A, a substrate 100 is provided. The substrate 100 has a semiconductor device or a metallic interconnect (not shown) disposed therein, for example. The uppermost layer is an inter-layer dielectric (ILD, not shown), for example. The contact will form in the inter-layer dielectric (ILD) layer so that the semiconductor device or the metallic interconnect can electrically connect with the outside. Then, a mask layer 102 is formed over the substrate 100. The mask layer 102 is fabricated using a material having a significantly different etching selectivity relative to the inter-layer dielectric (ILD) layer. If the ILD layer is fabricated using silicon oxide, the mask layer 102 is preferably a silicon nitride layer formed by a chemical vapor deposition process. Thereafter, a patterned photoresist layer 104 is formed over the mask layer 102. The patterned photoresist layer 104 is fabricated using a positive photoresist or a negative photoresist, for example. The method of forming the patterned photoresist layer 104 includes forming a first photoresist layer (not shown) over the mask layer 102. Then, a exposure process is performed using a photomask (not shown) with line openings in the ‘y’ direction, and then a developing process is performed to form at least a trench 105 extending in the ‘y’ direction in the first photoresist layer. The trench 105 exposes a portion of the mask layer 102. Thereafter, part of the mask layer 102 is removed to from a plurality of trenches 106 (can be seen in FIG. 1B) in the mask layer 102 by using the patterned photoresist layer 104 as a mask. The trenches 106 are arranged in parallel to each other. The method of removing part of the mask layer 102 includes performing a dry etching operation 108, for example.

As shown in FIG. 1B, the trenches 106 have a depth d1 smaller than the thickness t of the mask layer 102 and extends in a ‘y’ direction. Then, the patterned photoresist layer 104 is removed. The method of removing the patterned photoresist layer 104 includes performing an ashing operation and performing a cleaning operation using an RCA solution as the cleaning agent, for example.

As shown in FIG. 1C, another patterned photoresist layer 110 is formed over the mask layer 102. The patterned photoresist layer 110 is fabricated using a positive photoresist material or a negative photoresist material, for example. The method of forming the patterned photoresist layer 110 includes forming a second photoresist layer (not shown) over the mask layer 102. Then, a exposure process is performed by using a photomask (not shown) with line openings running in the ‘x’ direction, and then a developing process is performed to form at least a trench 107 extending in the ‘x’ direction and exposing the mask layer 102 in the second photoresist layer. The ‘x’ direction and the ‘y’ direction cross over each other. Thereafter, part of the mask layer 102 is removed to form a plurality of trenches 112 (shown in FIG. 1D) in the mask layer 102 by using the patterned photoresist layer 110 as a mask. The trenches 112 are arranged in parallel to each other. The method of removing part of the mask layer 102 includes performing a dry etching operation 114, for example.

As shown in FIG. 1D, the trenches 112 have a depth d2 smaller than the thickness t of the mask layer 102 and extend in the ‘x’ direction. Furthermore, there is an opening 116 at the location where the trench 112 and the trench 106 cross over each other. The openings 116 expose a portion of the substrate 100. The substrate 100 under the openings 116 are the locations for forming the contact holes in a subsequent operation. Then, using the patterned photoresist layer 110 and the mask layer 102 as a mask, part of the substrate 100 is removed to form contact holes in the substrate 100. Alternatively, the patterned photoresist layer 110 can be removed so that only the mask layer 102 is used as a mask to remove part of the substrate 100 and form the contact holes in the substrate 100. Obviously, the need for removing the patterned photoresist layer 110 depends on the actual processing requirements. The method of removing the patterned photoresist layer 110 includes performing an ashing operation and performing a cleaning operation using an RCA solution as the cleaning agent. The method of removing part of the substrate 100 exposed by the opening 116 includes performing a dry etching operation 118, for example.

The thickness of any part of the mask layer 102 must be big enough to resist the dry etching operation 118. FIG. 2 is a top view of FIG. 1D. As shown in FIG. 2, the substrate 100 can be divided into areas A, B, C and D. Since areas A have not gone through any of the dry etching operations 108 or 114, the mask layer 102 in areas A has the original thickness. Due to the formation of the trenches 106 and 112, the mask layer 102 in areas B and D has a thickness smaller than the original thickness of the mask layer 102 but a sufficient thickness to withstand the dry etching operation 118. Since the openings 116 in areas C expose part of the substrate 100 through the openings 116, the mask layer 102 in areas C is completely removed.

As shown in FIGS. 2 and 1E, after aforesaid steps, a plurality of contact holes 120 has already formed in the substrate 100. Because the mask layer 102 in areas B and D must have a sufficient thickness to withstand the dry etching operation 118, the etching depth of the trenches 106 and 112 will be smaller than the thickness t of the mask layer 102. This ensures that the dry etching operation 118 will not damage the mask layer 102 in areas B and D and expose the substrate 100. Thus, the actual dimension of the contact hole 120 and the designed dimension are guaranteed to match and trenches are prevented from forming over the substrate 100 to bring out electrical problems in the subsequently formed contact plug.

In general, for an optical exposure system having the same hole diameter and source wavelength, the pattern dimension of micro-lines and trenches can be fabricated more accurately while a hole pattern has optical properties that are much harder to control. In the present invention, the very stable and highly etching selective characteristics of a mask layer is utilized and a trench pattern is used in a lithographic operation to produce a mask for forming the contact holes. Hence, the focusing depth and the exposure tolerance of the contact hole is increased. As a result, the processing capability for forming the contact hole is on par with the processing of a line or a trench. Furthermore, in the fabrication of the photomask, the fabrication of a line pattern is easier and more accurate than the fabrication of a dot pattern and hence is much cheaper to produce. Moreover, in the design of the photomask, the optical characteristics of a line pattern are easier to manage than the optical characteristics of a dot pattern. Therefore, considerable time is saved in designing a line pattern and the amount of information related to each photomask is substantially reduced. In addition, the present invention not only significantly lowers the degree of difficulties in the processing operation and simplifies the processing steps, but also provides a more stable structure.

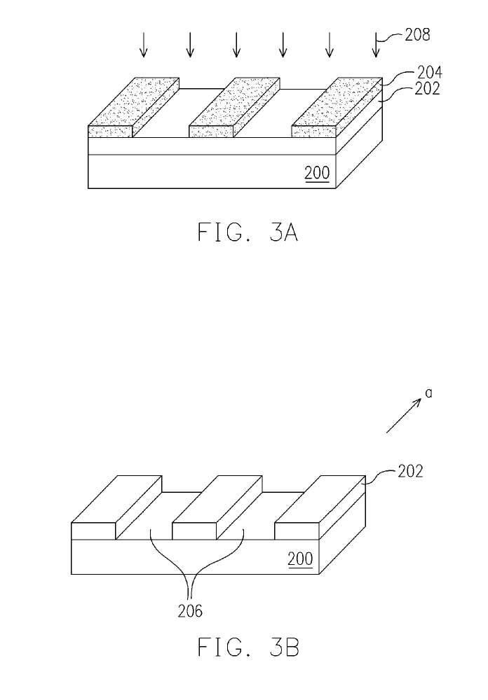

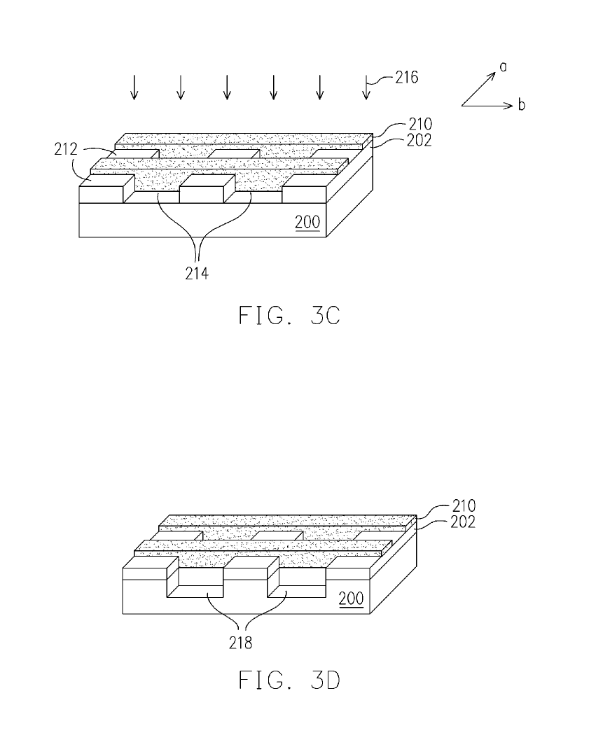

FIGS. 3A through 3D are perspective views showing the steps for fabricating contact holes on a substrate according to another embodiment of the present invention. The term ‘contact hole’ is a generic term for all kinds of contact holes, via holes and other types having a similar structure.

First, as shown in FIG. 3A, a substrate 200 is provided. The substrate 200 has a semiconductor device or a metallic interconnect (not shown) disposed therein, for example. The uppermost layer is an inter-layer dielectric (ILD, not shown), for example. The contact will form in the inter-layer dielectric (ILD) layer so that the semiconductor device or the metallic interconnect can electrically connect with the outside. Then, a mask layer 202 is formed over the substrate 200. The mask layer 202 is fabricated using a material having a significantly different etching selectivity relative to the inter-layer dielectric (ILD) layer. If the ILD layer is fabricated using silicon oxide, the mask layer 202 is preferably a silicon nitride layer formed by a chemical vapor deposition process. Thereafter, a patterned photoresist layer 204 is formed over the mask layer 202. The patterned photoresist layer 204 is formed using a method identical to the first embodiment and can be fabricated using a positive photoresist or a negative photoresist, for example. Then, part of the mask layer 202 is removed to from a plurality of trenches 206 (can be seen in FIG. 3B) in the mask layer 202 by using the patterned photomask 204 as a mask. The trenches 206 are arranged in parallel to each other, for example. The method of removing part of the mask layer 202 includes performing a dry etching operation 208, for example.

As shown in FIG. 3B, the trenches 206 extend in the ‘a’ direction and expose part of the substrate 200. Then, the patterned photoresist layer 204 is removed. The method of removing the patterned photoresist layer 204 includes performing an ashing operation and performing a cleaning operation using an RCA solution as the cleaning agent, for example.

As shown in FIG. 3C, another patterned photoresist layer 210 is formed on the substrate 200 and the mask layer 202. The patterned photoresist layer 210 can be fabricated using a positive photoresist material or a negative photoresist material, for example. The patterned photoresist layer 210 has a plurality of trenches 212. The trenches 212 are arranged in parallel to one another and extend in a ‘b’ direction such that the ‘b’ direction intersects the ‘a’ direction. In addition, the crossover location 214 where the trench 212 intersects the trench 206 exposes the substrate 200.

As shown in FIG. 3D, a dry etching operation 216 is performed to remove part of the exposed substrate 200 in the crossover location 214 by using the mask layer 202 and the patterned photoresist layer 210 as a mask. Hence, the foregoing process has produced a plurality of contact holes 218 in the substrate 200.

In summary, the present invention utilizes two separate masks including a mask layer with trench pattern thereon and a patterned photoresist layer to form a contact hole in the substrate so that the harder-to-produce contact hole pattern in a photolithographic process can have a wider processing window. In addition, in the fabrication and design of the photomask, the optical characteristics of a line pattern is much easier to manage than a dot pattern so that design and fabrication of line pattern on a photomask is much simpler. As a result, the production cost can be significantly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a contact hole, comprising:
providing a substrate;
forming a mask layer over the substrate;
forming at least a first trench in the mask layer, wherein the depth of the first trench is not greater than the thickness of the mask layer and the first trench extends in a first direction;
forming at least a second trench in the mask layer, wherein the depth of the second trench is not greater than the thickness of the mask layer and the second trench extends in a second direction such that the second direction intersects the first direction, and there is an opening that exposes part of the substrate at the crossover location between the second trench and the first trench; and
removing part of the substrate exposed by the opening.

2. The method of claim 1, wherein the step of forming at least one first trench in the mask layer comprises:
forming a first patterned photoresist layer over the mask layer;
removing part of the mask layer using the first patterned photoresist layer as a mask to form at least the first trench in the mask layer; and
removing the first patterned photoresist layer.

3. The method of claim 2, wherein the material constituting the first patterned photoresist layer comprises positive photoresist or negative photoresist.

4. The method of claim 1, wherein the step of forming at least one second trench in the mask layer comprises:
forming a second patterned photoresist layer over the mask layer; and
removing part of the mask layer by using the second patterned photoresist layer as a mask to form at least a second trench in the mask layer.

5. The method of claim 4, after forming the second trench in the mask layer but before removing part of the substrate exposed by the opening, further comprising removing the second patterned photoresist layer.

6. The method of claim 4, wherein the material constituting the second photoresist layer comprises positive photoresist or negative photoresist.

7. The method of claim 1, wherein the first trench exposes the substrate.

8. The method of claim 1, wherein the material constituting the mask layer comprises silicon nitride.

9. A method of fabricating a contact hole, comprising:
providing a substrate;
forming a mask layer over the substrate;
forming a first photoresist layer over the mask layer;
performing a first exposure process to the first photoresist layer by using a first photomask, wherein the first photomask has at least a first line opening and the first line opening extends in a first direction;
performing a first developing process to form at least a first trench that exposes the mask layer in the first photoresist layer, wherein the first trench extends in the first direction;
performing a first etching operation by using the first photoresist layer as a mask to form at least a second trench in the mask layer, wherein the depth of the second trench is not greater than the thickness of the mask layer;
removing the first photoresist layer;
forming a second photoresist layer over the substrate;
performing a second exposure process to the second photoresist layer by using a second photomask, wherein the second photomask has at least a second line opening and the second line opening extends in a second direction;
performing a second developing process to form at least a third trench that exposes the mask layer in the second photoresist layer, wherein the second direction intersects the first direction;
performing a second etching operation by using the second photoresist layer as a mask to form at least a fourth trench in the mask layer, wherein the depth of the fourth trench is not greater than the thickness of the mask layer and the crossover area between the second trench and the fourth trench expose part of the substrate; and
removing part of the exposed substrate.

10. The method of claim 9, after forming the fourth trench but before removing part of the exposed substrate, further comprising removing the second photoresist layer.

11. The method of claim 9, wherein the material constituting the first photoresist layer comprises positive photoresist or negative photoresist.

12. The method of claim 9, wherein the material constituting the second photoresist layer comprises positive photoresist or negative photoresist.

13. The method of claim 9, wherein the material constituting the mask layer comprises silicon nitride.
